(19) United States
(12) Patent Application Publication
(10) Pub. No.: US 2024/0395720 A1
(43) Pub. Date: Nov. 28, 2024

(54) SEMICONDUCTOR PACKAGE AND METHOD FOR MANUFACTURING THE SAME

(71) Applicant: SAMSUNG ELECTRONICS CO., LTD., SUWON-SI (KR)

(72) Inventors: CHOONGBIN YIM, Suwon-si (KR); JONGKOOK KIM, Suwon-si (KR)

(21) Appl. No.: 18/395,821

(22) Filed: Dec. 26, 2023

(30) Foreign Application Priority Data
May 24, 2023 (KR) 10-2023-0067116

(51) Int. Cl. H01L 23/538; H01L 21/56; H01L 23/00; H01L 23/31; H01L 23/48; H01L 25/00; H01L 25/065; H01L 25/10; H10B 80/00

(52) U.S. Cl. CPC H01L 23/5384; H01L 21/56; H01L 23/3128; H01L 23/481; H01L 23/5383; H01L 25/0652; H01L 25/105; H01L 25/50; H10B 80/00; H01L 24/08; H01L 2224/08145; H01L 2224/08235

(57) ABSTRACT

A semiconductor package includes: a first redistribution layer structure; a first semiconductor die disposed on the first redistribution layer structure; a second semiconductor die disposed adjacent to the first semiconductor die on the first redistribution layer structure; a molding material positioned on the first redistribution layer structure, and covering the first semiconductor die and the second semiconductor die; a bridge die positioned on the molding material, the first semiconductor die, and the second semiconductor die, and electrically connecting the first semiconductor die and the second semiconductor die to each other; a substrate positioned on the molding material, the first semiconductor die, and the second semiconductor die, and at least partially surrounding the bridge die; and a second redistribution layer structure disposed on the bridge die and the substrate.

### CROSS-REFERENCE TO RELATED APPLICATION

This application claims priority under 35 U.S.C. § 119 to Korean Patent Application No. 10-2023-0067116, filed in the Korean Intellectual Property Office on May 24, 2023, the disclosure of which is incorporated by reference herein in its entirety.

### TECHNICAL FIELD

The present inventive concept relates to a semiconductor package and a method for manufacturing the same.

### DISCUSSION OF THE RELATED ART

The semiconductor industry seeks to increase integration density so that more passive and/or active devices can be integrated within a given area. Among them, the development of technology for miniaturizing a circuit line width of a semiconductor front-end process may have limitations, and accordingly, the semiconductor industry may supplement limitations of semiconductor front-end processes by developing semiconductor package techniques capable of having high integration densities. According to this trend, semiconductor chips are packaged by arranging them side by side, and a semiconductor package technique for vertically stacking packaged semiconductor packages has been under development.

An upper structure and a lower structure are electrically connected to each other by metal posts in the semiconductor package technique for packaging semiconductor dies by arranging them side by side and stacking the packaged semiconductor packages vertically. However, the metal posts may have a long electrical path between the upper structure and the lower structure, and such a long electrical path may make it difficult to implement a high-performance semiconductor package. To form a long metal post, a same process such as exposure, development, etching, and deposition should be repeatedly performed, and accordingly, a turn around time (TAT) may increase. Thus, a risk of yield degradation may occur in the process of forming the metal post.

In addition, as the metal posts should be positioned between semiconductor dies that are arranged side by side, a size of the semiconductor package may increase in the semiconductor package technique for packaging semiconductor dies by arranging them side by side and stacking the packaged semiconductor packages vertically.

### SUMMARY

According to an embodiment of the present inventive concept, a semiconductor package includes: a first redistribution layer structure; a first semiconductor die disposed on the first redistribution layer structure; a second semiconductor die disposed adjacent to the first semiconductor die on the first redistribution layer structure; a molding material positioned on the first redistribution layer structure, and covering the first semiconductor die and the second semiconductor die; a bridge die positioned on the molding material, the first semiconductor die, and the second semiconductor die, and electrically connecting the first semiconductor die and the second semiconductor die to each other; a substrate positioned on the molding material, the first semiconductor die, and the second semiconductor die, and at least partially surrounding the bridge die; and a second redistribution layer structure disposed on the bridge die and the substrate.

According to an embodiment of the present inventive concept, a semiconductor package includes: a first redistribution layer structure; a first semiconductor die disposed on the first redistribution layer structure; a second semiconductor die disposed adjacent to the first semiconductor die on the first redistribution layer structure; a plurality of conductive posts disposed on the first redistribution layer structure; a first molding material positioned on the first redistribution layer structure and covering the first semiconductor die, the second semiconductor die, and the plurality of conductive posts; an interposer positioned on the first molding material, the plurality of conductive posts, the first semiconductor die, and the second semiconductor die; a third semiconductor die disposed on the interposer; a fourth semiconductor die disposed adjacent to the third semiconductor die on the interposer; and a second molding material positioned on the interposer, and covering the third semiconductor die and the fourth semiconductor die, wherein the interposer includes: a bridge die configured to electrically connect the first semiconductor die and the second semiconductor die to each other; a substrate positioned on the first molding material, the first semiconductor die, and the second semiconductor die, and at least partially surrounding the bridge die, wherein the substrate is electrically connected to the conductive posts; and a second redistribution layer structure disposed on the bridge die and the substrate.

According to an embodiment of the present inventive concept, a manufacturing method for a semiconductor package includes: mounting a first semiconductor die and a second semiconductor die on a first redistribution layer structure; forming a plurality of conductive posts on the first redistribution layer structure; molding the first semiconductor die, the second semiconductor die, and the conductive posts with a first molding material on the first redistribution layer structure; providing an interposer, wherein the interposer includes: a bridge die; a substrate at least partially surrounding the bridge die; and a second redistribution layer structure disposed on the substrate and the bridge die; electrically connecting a lower surface of the substrate to the plurality of conductive posts, and electrically connecting a lower surface of the bridge die to the first semiconductor die and the second semiconductor die; mounting a third semiconductor die and a fourth semiconductor die on the second redistribution layer structure; and molding the third semiconductor die and the fourth semiconductor die with a second molding material on the second redistribution layer structure.

### BRIEF DESCRIPTION OF THE DRAWINGS

FIG. 1 illustrates a cross-sectional view showing a semiconductor package according to an embodiment of the present inventive concept.

FIG. 2 illustrates a cross-sectional view showing a semiconductor package according to an embodiment of the present inventive concept.

FIG. 3 illustrates a cross-sectional view showing a step of attaching a substrate to a first carrier as one of steps for manufacturing an interposer in a method for manufacturing a semiconductor package according to an embodiment of the present inventive concept.

FIG. 4 illustrates a cross-sectional view showing a step of attaching a bridge die to a first carrier as one of the steps for manufacturing an interposer in a method for manufacturing a semiconductor package according to an embodiment of the present inventive concept.

FIG. 5 illustrates a cross-sectional view showing a step of molding a bridge die with a third molding material on a first carrier as one of the steps for manufacturing an interposer in a method for manufacturing a semiconductor package according to an embodiment of the present inventive concept.

FIG. 6 illustrates a cross-sectional view showing a step of planarizing a third molding material as one of the steps for manufacturing an interposer in a method for manufacturing a semiconductor package according to an embodiment of the present inventive concept.

FIG. 7 illustrates a cross-sectional view showing a step of forming a back side redistribution layer structure on a third molding material, a substrate, and a bridge die as one of the steps for manufacturing an interposer in a method for manufacturing a semiconductor package according to an embodiment of the present inventive concept.

FIG. 8 illustrates a cross-sectional view showing a step of debonding a first carrier from lower surfaces of a third molding material, a substrate, and a bridge die as one of the steps for manufacturing an interposer in a method for manufacturing a semiconductor package according to an embodiment of the present inventive concept.

FIG. 9 illustrates a cross-sectional view showing a cross-sectional view showing a step of forming a front side redistribution layer structure on a second carrier as one the step of a method for manufacturing a semiconductor package according to an embodiment of the present inventive concept. FIG. 9 to FIG. 15 and FIG. 18 to FIG. 20 illustrate a method for manufacturing the semiconductor package of FIG. 1 according to an embodiment of the present inventive concept. FIG. 9 to FIG. 13 and FIG. 16 and FIG. 17 illustrate a method for manufacturing the semiconductor package of FIG. 2 according to an embodiment of the present inventive concept. A description of FIG. 18 to FIG. 20 illustrating a method for manufacturing the semiconductor package of FIG. 1 may be applied to the method for manufacturing the semiconductor package of FIG. 2 following FIG. 17, according to an embodiment of the present inventive concept.

FIG. 10 illustrates a cross-sectional view showing a step of mounting a first semiconductor die and a second semiconductor die on a front side redistribution layer structure as one step of a method for manufacturing a semiconductor package according to an embodiment of the present inventive concept.

FIG. 11 illustrates a cross-sectional view showing a step of forming conductive posts on a front side redistribution layer structure as one step of a method for manufacturing a semiconductor package according to an embodiment of the present inventive concept.

FIG. 12 illustrates a cross-sectional view showing a step of molding conductive posts, a first semiconductor die, and a second semiconductor die with a first molding material on a front side redistribution layer structure as one step of a method for manufacturing a semiconductor package according to an embodiment of the present inventive concept.

FIG. 13 illustrates a cross-sectional view showing a step of planarizing a first molding material as one step of a method for manufacturing a semiconductor package according to an embodiment of the present inventive concept.

FIG. 14 illustrates a cross-sectional view showing a step of providing an interposer for hybrid bonding as one step of a method for manufacturing a semiconductor package according to an embodiment of the present inventive concept.

FIG. 15 illustrates a cross-sectional view showing a step of electrically connecting an interposer to conductive posts, a first semiconductor die, and a second semiconductor die by hybrid bonding as one step of a method for manufacturing a semiconductor package according to an embodiment of the present inventive concept.

FIG. 16 illustrates a cross-sectional view showing a step of providing an interposer for flip chip bonding, following FIG. 13, as one step of a method for manufacturing a semiconductor package according to an embodiment of the present inventive concept.

FIG. 17 illustrates a cross-sectional view showing a step of electrically connecting an interposer to conductive posts, a first semiconductor die, and a second semiconductor die by flip chip bonding as one step of a method for manufacturing a semiconductor package according to an embodiment of the present inventive concept.

FIG. 18 illustrates a cross-sectional view showing a step of mounting a third semiconductor die and a fourth semiconductor die on a back side redistribution layer structure as one step of a method for manufacturing a semiconductor package according to an embodiment of the present inventive concept.

FIG. 19 illustrates a cross-sectional view showing a step of molding a third semiconductor die and a fourth semiconductor die with a molding material on a back side redistribution layer structure as one step of a method for manufacturing a semiconductor package according to an embodiment of the present inventive concept.

FIG. 20 illustrates a cross-sectional view showing a step of debonding a second carrier from a lower surface of a front side redistribution layer structure as one step of a method for manufacturing a semiconductor package according to an embodiment of the present inventive concept.

### DETAILED DESCRIPTION

Embodiments of the present inventive concept will be described more fully hereinafter with reference to the accompanying drawings. As those skilled in the art would realize, the described embodiments may be modified in various different ways, all without departing from the spirit and scope of the present inventive concept.

The drawings and description are to be regarded as illustrative in nature and not restrictive. Like reference numerals designate like elements throughout the specification and drawings, and thus, their descriptions may be omitted.

In the drawings, various thicknesses, lengths, and angles are shown and while the arrangement shown does indeed represent an embodiment of the present inventive concept, it is to be understood that modifications of the various thicknesses, lengths, and angles may be possible within the spirit and scope of the present inventive concept and the present inventive concept is not necessarily limited to the particular thicknesses, lengths, and angles shown.

Throughout this specification and the claims that follow, when it is described that an element is “coupled/connected” to another element, the element may be “directly coupled/connected” to the other element or “indirectly coupled/connected” to the other element through a third element.

It will be understood that when an element such as a layer, film, region, or substrate is referred to as being “on” another element, it can be directly on the other element or intervening elements may also be present. In contrast, when an element is referred to as being “directly on” another element, there are no intervening elements present between the element and the other element. Further, in the specification, the word “on” or “above” means positioned on or below the object portion, and does not necessarily mean positioned on the upper side of the object portion based on a gravitational direction.

Further, throughout the specification, the phrase “in a plan view” means when an object portion is viewed from above unless indicated otherwise, and the phrase “in a cross-sectional view” means when a cross-section taken by vertically cutting an object portion is viewed from the side.

Hereinafter, a semiconductor package 100 and a manufacturing method for the semiconductor package 100 according to an embodiment of the present inventive concept will be described with reference to drawings.

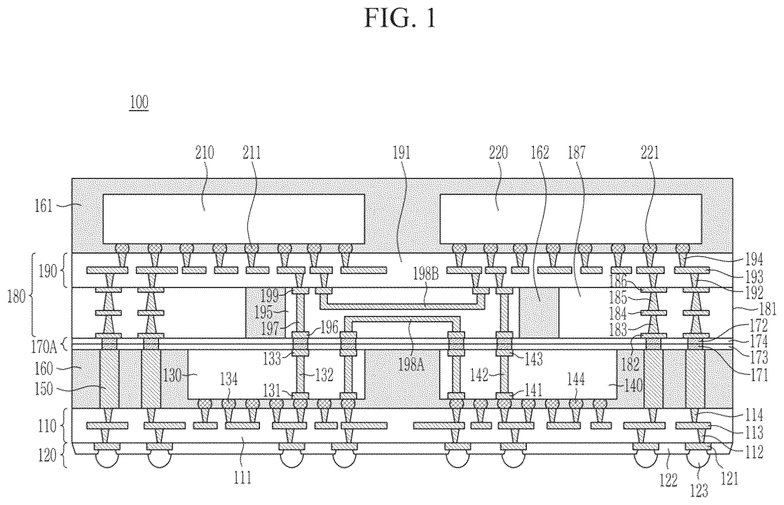

FIG. 1 illustrates a cross-sectional view showing a semiconductor package according to an embodiment of the present inventive concept including an interposer 180 electrically connecting a first semiconductor die 130, a second semiconductor die 140, a third semiconductor die 210, and a fourth semiconductor die 220 to each other. The interposer 180 includes a bridge die 195, a substrate 181 at least partially surrounding the bridge die 195, and a back side redistribution layer structure (e.g., a second redistribution layer structure 190) on the substrate 181 and the bridge die 195. The interposer 180 is electrically connected to the first semiconductor die 130, the second semiconductor die 140, and conductive posts 150 by hybrid bonding.

Referring to FIG. 1, the semiconductor package 100 may include a front side redistribution layer structure (e.g., the first redistribution layer structure) 110, an external connection structure 120, the first semiconductor die 130, the second semiconductor die 140, a first molding material 160, an interconnection structure 170A, the interposer 180, the third semiconductor die 210, the fourth semiconductor die 220, and a second molding material 161.

The front side redistribution layer structure 110 may include a first dielectric layer 111 and first redistribution layer vias 112, first redistribution layer lines 113, and second redistribution layer vias 114 within the first dielectric layer 111. In an embodiment of the present inventive concept, front side redistribution layer structures 110 that include fewer or greater numbers of redistribution layer lines and redistribution layer vias are within the scope of the present inventive concept.

The first redistribution layer via 112 may be positioned between the first redistribution layer line 113 and a conductive pad 121. The first redistribution layer via 112 may electrically connect the first redistribution layer line 113 to an external connection member 123 that is connected to the conductive pad 121. The first redistribution layer line 113 may be positioned between the first redistribution layer via 112 and the second redistribution layer via 114. The first redistribution layer line 113 may electrically connect the first redistribution layer via 112 and the second redistribution layer via 114. The second redistribution layer via 114 may be positioned between the first redistribution layer line 113 and the conductive post 150, between the first redistribution layer line 113 and a connection member 134 of the first semiconductor die 130, and between the first redistribution layer line 113 and a connection member 144 of the second semiconductor die 140. The second redistribution layer via 114 may electrically connect the conductive post 150 to the first redistribution layer line 113, the connection member 134 of the first semiconductor die 130 to the first redistribution layer line 113, and the connection member 144 of the second semiconductor die 140 to the first redistribution layer line 113.

The external connection structure 120 may be positioned on a lower surface of the front side redistribution layer structure 110. The external connection structure 120 may include conductive pads 121, an insulating layer 122, and external connection members 123. The conductive pad 121 may electrically connect the first redistribution layer via 112 of the front side redistribution layer structure 110 to the external connection member 123. The insulation layer 122 may include a plurality of openings for soldering. The insulating layer 122 may prevent the external connection member 123 from being short-circuited. The external connection member 123 may electrically connect the semiconductor package 100 to an external device.

The first semiconductor die 130 may be positioned on the front side redistribution layer structure 110. The first semiconductor die 130 may include first connection pads 131, through first silicon vias (TSVs) 132, second connection pads 133, and connection members 134. In an embodiment of the present inventive concept, the first semiconductor die 130 may include an application processor (AP).

The first connection pad 131 may be positioned between the first through silicon via (TSV) 132 and the connection member 134. The first connection pad 131 may electrically connect the first through silicon via (TSV) 132 to the connection member 134.

The first through silicon via (TSV) 132 may be positioned between the first connection pad 131 and the second connection pad 133. The first through silicon via (TSV) 132 may electrically connect the second connection pad 133 to the first connection pad 131. A first end of the first through silicon via (TSV) 132 may be connected to the first connection pad 131, and a second end of the first through silicon via (TSV) 132 may be connected to the second connection pad 133.

The second connection pad 133 may be positioned between the first through silicon via (TSV) 132 and a first bonding pad 171 of the interconnection structure 170A. The second connection pad 133 may electrically connect the first bonding pad 171 of the interconnection structure 170A to the first through silicon via (TSV) 132. For example, the second connection pad 133 may be directly bonded to the first bonding pad 171 of the interconnection structure 170A.

The connection member 134 may electrically connect the first connection pad 131 to the second redistribution layer via 114 of the front side redistribution layer structure 110. In an embodiment of the present inventive concept, the connection member 134 may include a micro bump or a solder ball.

In an embodiment of the present inventive concept, the first through silicon via (TSV) 132 may include at least one of tungsten, aluminum, copper, or an alloy thereof. In an embodiment of the present inventive concept, each of the first connection pad 131 and the second connection pad 133 may include at least one of copper, aluminum, silver, tin, gold, nickel, lead, titanium, or an alloy thereof. In an embodiment of the present inventive concept, the connection member 134 may include at least one of tin, silver, lead, nickel, copper, or an alloy thereof.

The second semiconductor die 140 may be positioned on the front side redistribution layer structure 110. The first semiconductor die 140 may include third connection pads 141, second through silicon vias (TSVs) 142, fourth connection pads 143, and connection members 144. The second semiconductor die 140 may include a memory semiconductor.

The third connection pad 141 may be positioned between the second through silicon via (TSV) 142 and the connection member 144. The third connection pad 141 may electrically connect the second through silicon via (TSV) 142 to the connection member 144.

The second through silicon via (TSV) 142 may be positioned between the third connection pad 141 and the fourth connection pad 143. The second through silicon via (TSV) 142 may electrically connect the fourth connection pad 143 to the third connection pad 141. A first end of the second through silicon via (TSV) 142 may be connected to the third connection pad 141, and a second end of the second through silicon via (TSV) 142 may be connected to the fourth connection pad 143.

The fourth connection pad 143 may be positioned between the second through silicon via (TSV) 142 and a first bonding pad 171 of the interconnection structure 170A. The fourth connection pad 143 may electrically connect the first bonding pad 171 of the interconnection structure 170A to the second through silicon via (TSV) 142. For example, the fourth connection pad 143 may be directly bonded to the first bonding pad 171 of the interconnection structure 170A.

The connection member 144 may electrically connect the third connection pad 141 to the second redistribution layer via 114 of the front side redistribution layer structure 110. In an embodiment of the present inventive concept, the connection member 144 may include a micro bump or a solder ball.

In an embodiment of the present inventive concept, the second through silicon via (TSV) 142 may include at least one of tungsten, aluminum, copper, or an alloy thereof. In an embodiment of the present inventive concept, each of the third connection pad 141 and the fourth connection pad 143 may include at least one of copper, aluminum, silver, tin, gold, nickel, lead, titanium, or an alloy thereof. In an embodiment of the present inventive concept, the connection member 144 may include at least one of tin, silver, lead, nickel, copper, or an alloy thereof.

The conductive posts 150 may be positioned on an upper surface of the front side redistribution layer structure 110. The conductive posts 150 may be positioned adjacent to a first side surface of the first semiconductor die 130 or the second semiconductor die 140. The conductive posts 150 might not be positioned between the first semiconductor die 130 and the second semiconductor die 140. The conductive posts 150 may be positioned to extend through the first molding material 160. A side surface of the conductive post 150 may be at least partially surrounded by the first molding material 160. The conductive post 150 may electrically connect the second redistribution layer via 114 of the front side redistribution layer structure 110 and the first bonding pad 171 of the interconnection structure 170A to each other. An upper surface of the conductive posts 150 may be coplanar with at least one of an upper surface of the first semiconductor die 130 and an upper surface of the second semiconductor die 140.

The first molding material 160 may be positioned on the front side redistribution layer structure 110, and may mold the first semiconductor die 130, the second semiconductor die 140, and the conductive posts 150.

The interconnection structure 170A may be positioned on the first semiconductor die 130, the second semiconductor die 140, the conductive posts 150, and the first molding material 160. The interconnection structure 170A may include first bonding pads 171, second bonding pads 172, first silicon insulating layer 173, and second silicon insulating layer 174. The first bonding pads 171 and the second bonding pads 172 may electrically connect the interposer 180 to first semiconductor die 130, the second semiconductor die 140, and the conductive posts 150.

In the semiconductor structure 100 according to an embodiment of the present inventive concept, the first semiconductor die 130 and the interposer 180, the second semiconductor die 140 and the interposer 180, and the conductive posts 150 and the interposer 180 may be bonded by hybrid bonding. The hybrid bonding is to bond two devices by fusing same materials of the two devices using a bonding property of a same material. Herein, hybrid indicates that two different types of bonding are made, e.g., bonding two devices with a first type of metal-metal bonding and a second type of non-metal-non-metal bonding. The hybrid bonding may make it possible to form I/Os with a fine pitch.

For example, the first bonding pads 171 may be directly bonded to the second bonding pads 172 by metal-metal hybrid bonding, and the first silicon insulation layer 173 may be directly bonded to the second silicon insulation layer 174 by non-metal-non-metal hybrid bonding.

The interposer 180 may be positioned on the interconnection structure 170A. The interposer 180 may include the substrate 181, the bridge die 195, the back side redistribution layer structure 190, and a third molding material 162. The interposer 180 has a function of electrically connecting a lower structure (the first semiconductor die 120, the second semiconductor die 130, and the front side redistribution layer structure 110) and an upper structure (the third semiconductor die 210 and the fourth semiconductor die 220) to each other. For example, the substrate 181 has a function of electrically connecting the front side redistribution layer structure 110 to the back side redistribution layer structure 190, which is connected to conductive posts having normal pitch I/Os. The bridge die 195 has a function of electrically connecting the first through silicon via (TSV) 132 of the first semiconductor die 130, which have fine pitch I/Os, and the second through silicon via (TSV) 142 of the second semiconductor die 140, which have fine pitch I/Os, to each other and the third semiconductor die 210, which has fine pitch I/Os, and the fourth semiconductor die 220, which has fine pitch I/Os, to each other. The back side redistribution layer structure 190 has a function of electrically connecting the third semiconductor die 210 and the fourth semiconductor die 220 to the substrate 181 and the bridge die 195, and compensating for a difference between fine pitch I/Os or normal pitch I/Os according to each configuration and electrically connecting them.

The substrate 181 may be positioned to at least partially surround the bridge die 195 on the interconnection structure 170A. The substrate 181 may include a first wiring layer 182, a first via 183, a second wiring layer 184, a second via 185, a third wiring layer 186, and an insulating layer 187. The substrate 181 may electrically connect the back side redistribution layer structure 190 to the front redistribution layer structure 110, which is connected to the conductive posts 150, through the interconnection structure 170A. In an embodiment of the present inventive concept, the substrate 181 may include a printed circuit board (PCB). In an embodiment of the present inventive concept, the substrate 181 may include an embedded trace substrate (ETS).

The first wiring layer 182 is positioned between the second bonding pad 172 and the first via 183 of the interconnection structure 170A. The first wiring layer 182 may electrically connect the first via 183 to the second bonding pad 172 of the interconnection structure 170A. The first via 183 is positioned between the first wiring layer 182 and the second wiring layer 184. The first via 183 may electrically connect the second wiring layer 184 to the first wiring layer 182. The second wiring layer 184 is disposed between the first via 183 and the second via 185. The second wiring layer 184 may electrically connect the second via 185 to the first via 183. The second via 185 is positioned between the second wiring layer 184 and the third wiring layer 186. The second via 185 may electrically connect the third wiring layer 186 to the second wiring layer 184. The third wiring layer 186 is disposed between the second via 185 and the third redistribution layer via 192 of the back side redistribution layer structure 190. The third wiring layer 186 may electrically connect the third redistribution layer via 192 of the back side redistribution layer structure 190 to the second via 185. The insulating layer 187 may at least partially surround the first wiring layer 182, the first via 183, the second wiring layer 184, the second via 185, and the third wiring layer 186. In the embodiment of the present inventive concept, with reference to FIG. 1, the substrate 181 includes two layers of vias, but the present inventive concept is not limited thereto. For example, the substrate 181 may include three or more multi-layers. In an embodiment of the present inventive concept, a substrate 181 that include fewer or greater numbers of wiring layers, and vias are within the scope of the present inventive concept.

In an embodiment of the present inventive concept, each of the first via 183 and the second via 185 may have a truncated cone shape in which a diameter becomes narrower from a lower surface to an upper surface. In an embodiment of the present inventive concept, each of the first via 183 and the second via 185 may have a truncated cone shape in which a diameter becomes narrower from an upper surface to a lower surface. In an embodiment of the present inventive concept, the first via 183 and the second via 185 may include a cylindrical shape having a constant diameter from an upper surface to a lower surface.

In an embodiment of the present inventive concept, the insulating layer 187 may include a thermosetting resin such as an epoxy resin, a thermoplastic resin such as polyimide, or a mixture of such a resin and an inorganic filler. In an embodiment of present inventive concept, the insulating layer 187 may include a resin impregnated into a core material such as glass fiber (e.g., glass fiber, glass cloth, or glass fabric) together with an inorganic filler. In an embodiment of the present inventive concept, the insulating layer 187 may include prepreg, an ajinomoto build-up film (ABF), FR-4, or bismaleimide triazine (BT). In an embodiment of the present inventive concept, the dielectric layer 187 may include a photosensitive insulator (photoimageable dielectric PID)). In an embodiment of the present inventive concept, the first wiring layer 182, the second wiring layer 184, and the third wiring layer 186 may each include at least one of copper, aluminum, silver, tin, gold, nickel, lead, titanium, or an alloy thereof. In an embodiment of the present inventive concept, the first via 183 and the second via 185 may each include at least one of copper, aluminum, silver, tin, gold, nickel, lead, titanium, or an alloy thereof.

The bridge die 195 may include lower connection pads 196, third through silicon vias (TSVs) 197, upper connection pads 199, a lower connection line 198A, and an upper connection line 198B. In an embodiment of the present inventive concept, the bridge die 195 may include a silicon bridge. A side surface of the bridge die 195 may be molded to the third molding material 162. The third through silicon via (TSV) 197 included in the bridge die 195 moves data quickly in the vertical direction, and the lower connection line 198A and the upper connection line 198B quickly move data in the horizontal direction. Accordingly, performance of the semiconductor package may be increased by reducing power consumption in the semiconductor package.

The third through silicon via (TSV) 197 may be positioned between the lower connection pad 196 and the upper connection pad 199. The third through silicon via 197 may electrically connect the third semiconductor die 210 and the fourth semiconductor die 220, which are connected to the back side redistribution layer structure 190, to the first semiconductor die 130 and the second semiconductor die 140, which are connected to the interconnection structure 170A, via the upper connection pad 199 and the lower connection pad 196 in the vertical direction.

The lower connection line 198A may be positioned between the lower connection pads 196, and may electrically connect the first semiconductor die 130 and the second semiconductor die 140 to each other, which are connected to the interconnection structure 170A via the lower connection pads 196.

The upper connection line 198B may be positioned between the upper connection pads 199, and may electrically connect the third semiconductor die 210 and the fourth semiconductor die 220 to each other, which are connected to the back side redistribution layer structure 190 via the upper connection pads 199.

In an embodiment of the present inventive concept, the third through silicon via (TSV) 197 may include at least one of tungsten, aluminum, copper, or an alloy thereof. Each of the lower connection pad 196 and the upper connection pad 199 may include at least one of copper, aluminum, silver, tin, gold, nickel, lead, titanium, or an alloy thereof. Each of the lower connection line 198A and the upper connection line 198B may include at least one of copper, aluminum, silver, tin, gold, nickel, lead, titanium, tungsten, or an alloy thereof.

According to an embodiment of present inventive concept, in a semiconductor package in which a lower structure in which the first semiconductor die 130 and the second semiconductor die 140 are positioned side by side and an upper structure in which the third semiconductor die 210 and the fourth semiconductor die 220 are positioned side by side are vertically stacked, the bridge die 195 may be used to electrically connect the upper semiconductor dies (the third semiconductor die 210 and the fourth semiconductor die 220) and the lower semiconductor dies (the first semiconductor die 130 and the second semiconductor die 140) and to electrically connect the semiconductor dies positioned side by side in each of the upper structure and the lower structure. Accordingly, a size of the semiconductor package can be reduced by using bridge dies above the first semiconductor die 130 and above the second semiconductor die 140 without positioning conductive posts with long electrical paths between the first semiconductor die 130 and the second semiconductor die 140. In addition, a length of an electrical path between the upper structure and the lower structure may be reduced by reducing a height of the conductive posts positioned at first sides of the first semiconductor die 130 and the second semiconductor die 140. In addition, by reducing use of metal posts in the semiconductor package, a turn around time may be reduced and yield may be increased.

The back side redistribution layer structure 190 may be positioned on the substrate 181, the bridge die 195, and the third molding material 162. The back side redistribution layer structure 190 may include a second dielectric layer 191 and third redistribution layer vias 192, second redistribution layer lines 193, and fourth redistribution layer vias 194 within the second dielectric layer 191. In an embodiment of the present inventive concept, back side redistribution layer structures 190 that include fewer or greater numbers of redistribution layer lines and redistribution layer vias are within the scope of the present inventive concept.

The second dielectric layer 191 may protect and insulate the third redistribution layer vias 192, the second redistribution layer lines 193, and the fourth redistribution layer vias 194. The third semiconductor die 210 and the fourth semiconductor die 220 may be positioned on an upper surface of the second dielectric layer 191. The substrate 181, the bridge die 195, and the third molding material 162 may be positioned on a lower surface of the second dielectric layer 191.

The third redistribution layer via 192 may be positioned between the third wiring layer 186 and the second redistribution layer line 193 of the substrate 181, and between the upper connection pad 199 of the bridge die 195 and the second redistribution layer line 193. The third redistribution layer via 192 may electrically connect the second wire line 193 to the third wiring layer 186 of the substrate 181 and the second wire line 193 to the upper connection pad 199 of the bridge die 195. The second redistribution layer line 193 may be positioned between the third redistribution layer via 192 and the fourth redistribution layer via 194. The second redistribution layer line 193 may electrically connect the third redistribution layer via 192 and the fourth redistribution layer via 194 to each other. The fourth redistribution layer via 194 may be positioned between the second redistribution layer line 193 and the connection member 211 of the third semiconductor die 210, and between the second redistribution layer line 193 and the connection member 221 of the fourth semiconductor die 220. The fourth redistribution layer via 194 may electrically connect the connection member 211 of the third semiconductor die 210 to the second redistribution layer line 193, and the connection member 221 of the fourth semiconductor die 220 to the second redistribution layer line 193.

The third semiconductor die 210 may be positioned on the back side redistribution layer structure 190. In an embodiment of the present inventive concept, the third semiconductor die 210 may include an application processor (AP). The third semiconductor die 210 may include connection members 211. The connecting member 211 may electrically connect the third semiconductor die 210 to the back side redistribution layer structure 190. In an embodiment of the present inventive concept, the connection member 211 may include a micro bump or a solder ball. In an embodiment of the present inventive concept, the connection member 211 may include at least one of tin, silver, lead, nickel, copper, or an alloy thereof.

The fourth semiconductor die 220 may be positioned on the back side redistribution layer structure 190. In an embodiment of the present inventive concept, the fourth semiconductor die 220 may include a memory semiconductor. The fourth semiconductor die 220 may include connection members 221. The connecting member 221 may electrically connect the fourth semiconductor die 220 to the back side redistribution layer structure 190. In an embodiment of the present inventive concept, the connection member 221 may include a micro bump or a solder ball. In an embodiment of the present inventive concept, the connection member 221 may include at least one of tin, silver, lead, nickel, copper, or an alloy thereof.

The second molding material 161 may be positioned on the back side redistribution layer structure 190, and may mold the third semiconductor die 210 and the fourth semiconductor die 220.

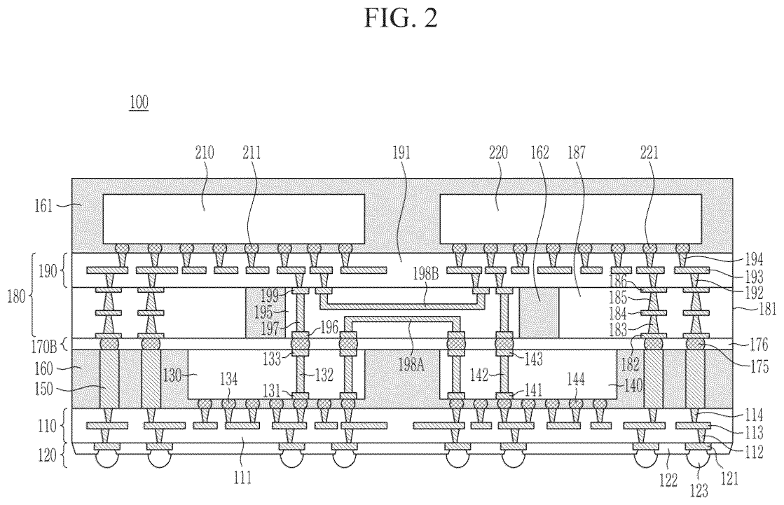

FIG. 2 illustrates a cross-sectional view showing a semiconductor package including an interposer 180 electrically connecting a first semiconductor die 130, a second semiconductor die 140, a third semiconductor die 210, and a fourth semiconductor die 220 to each other. The interposer 180 includes a bridge die 195, a substrate 181 at least partially surrounding the bridge die 195, and the back side redistribution layer structure 190 on the substrate 181 and the bridge die 195. The interposer 180 may be electrically connected to the first semiconductor die 130, the second semiconductor die 140, and conductive posts 150 by flip chip bonding.

Referring to FIG. 2, the interposer 180 may be electrically connected to the first semiconductor die 130, the second semiconductor die 140, and the conductive posts 150 through flip chip bonding. The interconnection member 170B may include connection members 175 for flip chip bonding and an insulating member 176 surrounding the connection members 175. The connection member 175 electrically connects the first wiring layer 182 of the substrate 181 to the conductive posts 150, and the lower connection pad 196 of the bridge die 195 to the second connection pad 133 of the first semiconductor die 130 and to the fourth connection pad 143 of the second semiconductor die 140. In an embodiment of the present inventive concept, the connection member 175 may include a micro bump or a solder ball. In an embodiment of present inventive concept, the connection member 175 may include at least one of tin, silver, lead, nickel, copper, or an alloy thereof. An insulating member 176 at least partially surrounds and protects the connection members 175 between the first semiconductor die 130 and the interposer 180, between the second semiconductor die 140 and the interposer 180, and between the conductive posts 150 and the interposer 180. In an embodiment of the present inventive concept, the insulating member 176 may include a molded under-fill (MUF). In an embodiment of the present inventive concept, the insulating member 176 may include a non-conductive film (NCF).

In FIG. 2, other configurations other than the interconnection member 170B are the same as those described in FIG. 1. Accordingly, the contents described in FIG. 1 may be equally applied to components other than the interconnection member 170B in FIG. 2.

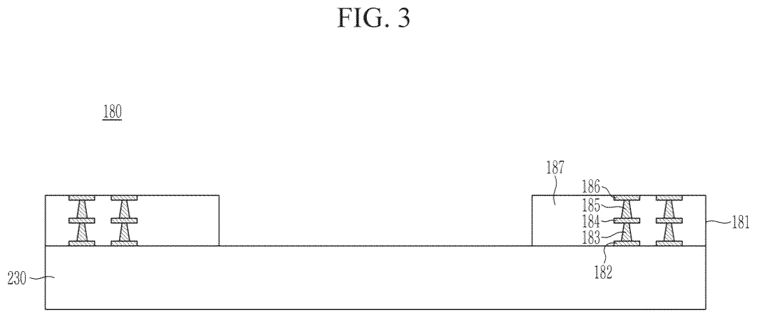

FIG. 3 illustrates a cross-sectional view showing a step of attaching the substrate 181 to the first carrier 230 as one of steps for manufacturing the interposer 180 in a method for manufacturing the semiconductor package 100 according to an embodiment of the present inventive concept.

Referring to FIG. 3, first, the first carrier 230 is provided. The first carrier 230 may include, e.g., a silicon-based material such as glass or a silicon oxide, an organic material, or another material such as an aluminum oxide, any combination of these materials, and the like. The first carrier 230 may include, e.g., a silicon-based material such as glass or a silicon oxide, an organic material, or another material such as an aluminum oxide, any combination of these materials, and the like.

Then, the substrate 181 is mounted on the first carrier 230. In an embodiment of the present inventive concept, the substrate 181 may be attached on the first carrier 230 by a laser.

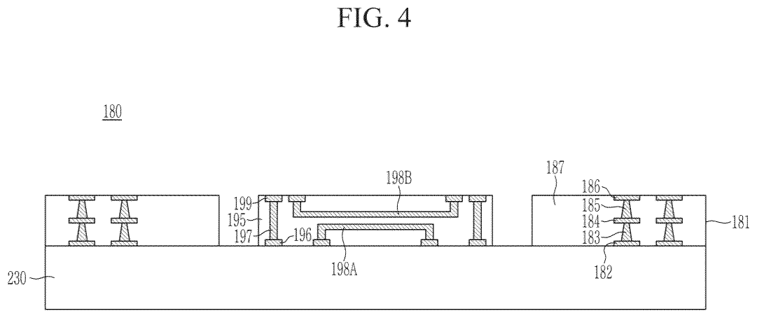

FIG. 4 illustrates a cross-sectional view showing a step of attaching the bridge die 195 to the first carrier 230 as one of steps for manufacturing the interposer 180 in a method for manufacturing the semiconductor package 100 according to an embodiment of the present inventive concept.

Referring to FIG. 4, the bridge die 195 is mounted on the first carrier 230. In an embodiment of the present inventive concept, the bridge die 195 may be attached on the first carrier 230 by a laser. As illustrated in FIG. 3 and FIG. 4, the substrate 181 was first attached on the first carrier 230, and then the bridge die 195 was attached. However, the present inventive concept is not limited thereto. In an embodiment of the present inventive concept, the bridge die 195 may be attached to the first carrier 230 first, followed by the substrate 181 attached thereto.

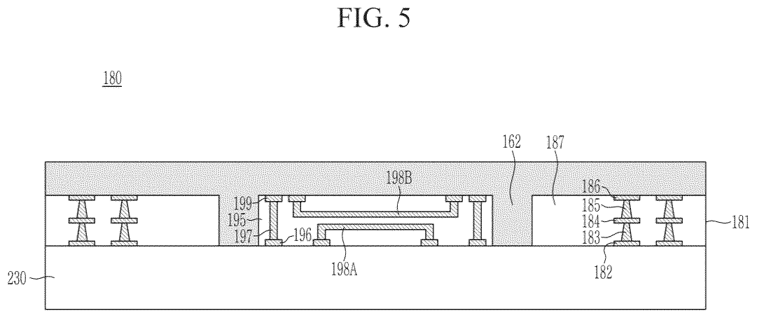

FIG. 5 illustrates a cross-sectional view showing a step of molding the bridge die 195 with the third molding material 162 on the first carrier 230 as one step of manufacturing the interposer 180 in a method for manufacturing the semiconductor package 100 according to an embodiment of the present inventive concept.

Referring to FIG. 5, the bridge die 195 is molded on the first carrier 230 with the third molding material 162. In an embodiment of the present inventive concept, the molding process with the third molding material 162 may include a compression molding or transfer molding process. In an embodiment of the present inventive concept, the third molding material 162 may include an epoxy molding compound (EMC). In an embodiment of the present inventive concept, the third molding material 162 may include an ajinomoto build-up film (ABF).

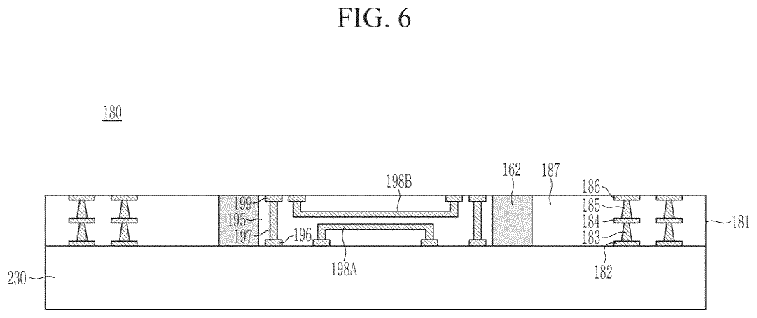

FIG. 6 illustrates a cross-sectional view showing a step of planarizing the third molding material 162 as one of the steps for manufacturing the interposer 180 in a method for manufacturing the semiconductor package 100 according to an embodiment of the present inventive concept.

Referring to FIG. 6, chemical mechanical polishing (CMP) is performed to level an upper surface of the third molding material 162. The upper surface of the third molding material 162 is planarized by applying a CMP process. After performing the CMP process, the upper connection pads 199 are exposed at an upper surface of the bridge die 195, and the third wiring layer 186 is exposed at an upper surface of the substrate 181.

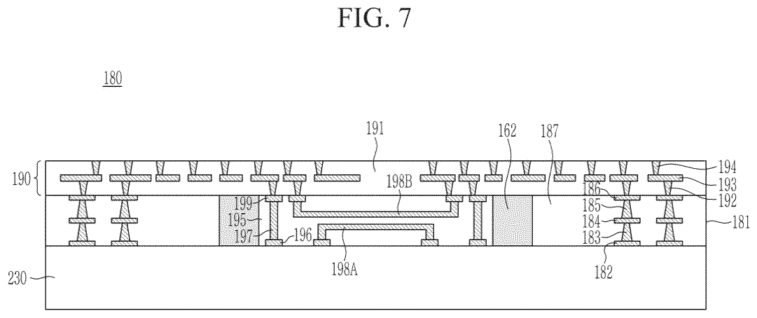

FIG. 7 illustrates a cross-sectional view showing a step of forming the back side redistribution layer structure 190 on the third molding material 162, the substrate 181, and the bridge die 195 as one of the steps for manufacturing the interposer 180 in a method for manufacturing the semiconductor package 100 according to an embodiment of the present inventive concept.

Referring to FIG. 7, the back side redistribution layer structure 190 is positioned on the third molding material 162, the substrate 181, and the bridge die 195.

First, the second dielectric layer 191 is disposed on the third molding material 162, the substrate 181, and the bridge die 195. In an embodiment of the present inventive concept, the second dielectric layer 191 may include a photosensitive polymer layer. The photosensitive polymer is a material capable of forming fine patterns by applying a photolithography process. In an embodiment of the present inventive concept, the second dielectric layer 191 may include a photosensitive insulator (photoimageable dielectric (PID)) used in a redistribution layer process. As an embodiment of the present inventive concept, the photoimageable dielectric (PID) may include a polyimide-based photosensitive polymer, a novolak-based photosensitive polymer, polybenzoxazole, a silicone-based polymer, an acrylate-based polymer, or an epoxy-based polymer. In an embodiment of the present inventive concept, the second dielectric layer 191 is formed of an inorganic dielectric material such as a silicon nitride, a silicon oxide, or the like. In an embodiment of the present inventive concept, the second dielectric layer 191 may be formed by a CVD, ALD, or PECVD process.

After forming the second dielectric layer 191, via holes are formed by selectively etching the second dielectric layer 191, and the third redistribution layer vias 192 are formed by filling the via holes with a conductive material.

Then, the second dielectric layer 191 is additionally deposited on the third redistribution layer vias 192 and the second dielectric layer 191, and the additionally deposited second dielectric layer 191 is selectively etched to form openings. The second redistribution layer lines 193 are formed by filling the openings with a conductive material.

Then, the second dielectric layer 191 is additionally deposited on the second redistribution layer lines 193 and the second dielectric layer 191, and the additionally deposited second dielectric layer 191 is selectively etched to form via holes. The fourth redistribution layer vias 194 are formed by filling the via holes with a conductive material.

In an embodiment of the present inventive concept, the third redistribution layer vias 192, the second redistribution layer lines 193, and the fourth redistribution layer vias 194 may include at least one of copper, aluminum, tungsten, nickel, gold, tin, titanium, or an alloy thereof. In an embodiment of the present inventive concept, the third redistribution layer vias 192, the second redistribution layer lines 193, and the fourth redistribution layer vias 194 may be formed by performing a sputtering process. In an embodiment of the present inventive concept, the third redistribution layer vias 192, the second redistribution layer lines 193, and the fourth redistribution layer vias 194 may be formed by performing an electrolytic plating process after forming a seed metal layer.

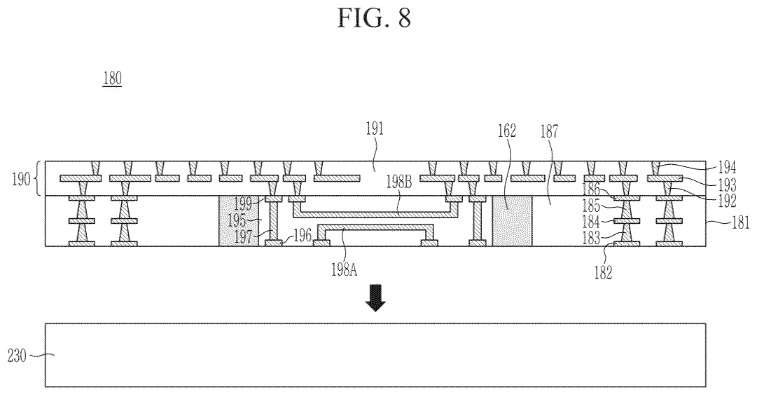

FIG. 8 illustrates a cross-sectional view showing a step of debonding the first carrier 230 from lower surfaces of the third molding material 162, the substrate 181, and the bridge die 195 as one of the steps for manufacturing the interposer 180 in a method for manufacturing the semiconductor package 100 according to an embodiment of the present inventive concept.

Referring to FIG. 8, the first carrier 230 is debonded from the lower surfaces of the third molding material 162, the substrate 181, and the bridge die 195.

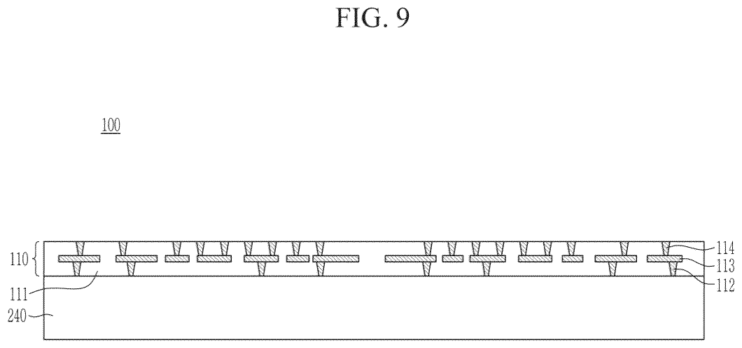

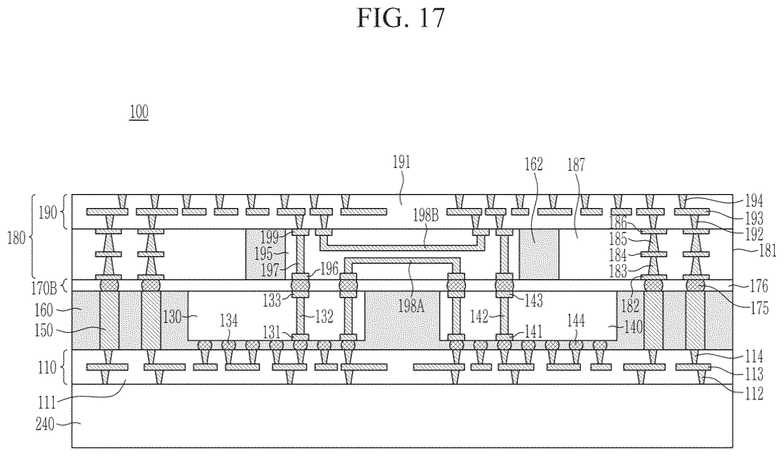

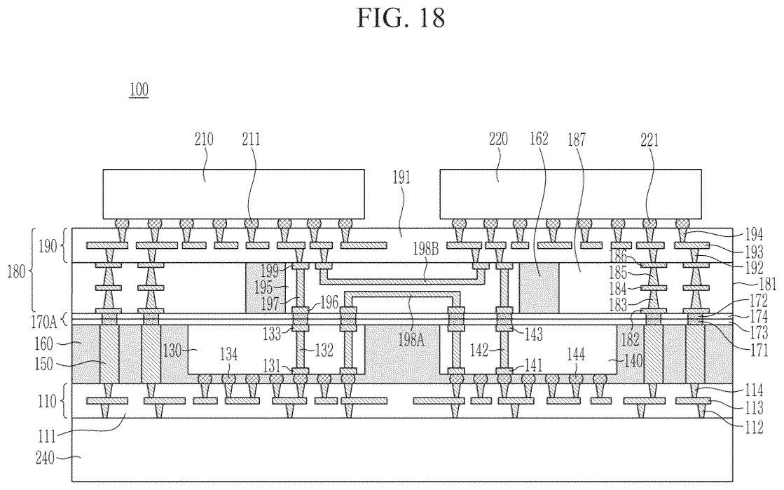

FIG. 9 illustrates a cross-sectional view showing a step of forming the front side redistribution layer structure 110 on the second carrier 240 as one step of a method for manufacturing the semiconductor package 100 according to an embodiment of the present inventive concept. FIG. 9 to FIG. 15 and FIG. 18 to FIG. 20 illustrate a method for manufacturing the semiconductor package 100 of FIG. 1 according to an embodiment of the present inventive concept. FIG. 9 to FIG. 13 and FIG. 16 and FIG. 17 illustrate a method for manufacturing the semiconductor package 100 of FIG. 2 according to an embodiment of the present inventive concept. A description of FIG. 18 to FIG. 20 illustrating a method for manufacturing the semiconductor package 100 of FIG. 1 may be applied to the method for manufacturing the semiconductor package 100 of FIG. 2 following FIG. 17 according to an embodiment of the present inventive concept.

Referring to FIG. 9, first, the first dielectric layer 111 is disposed on the second carrier 240. In an embodiment of the present inventive concept, the first dielectric layer 111 may include a photosensitive polymer layer. The photosensitive polymer is a material capable of forming fine patterns by applying a photolithography process. In an embodiment of the present inventive concept, the first dielectric layer 111 may include a photosensitive insulator (photoimageable dielectric (PID)) used in a redistribution layer process. As an embodiment of the present inventive concept, the photoimageable dielectric (PID) may include a polyimide-based photosensitive polymer, a novolak-based photosensitive polymer, polybenzoxazole, a silicone-based polymer, an acrylate-based polymer, or an epoxy-based polymer. In an embodiment of the present inventive concept, the first dielectric layer 111 is formed of a polymer such as PBO and polyimide. In an embodiment of the present inventive concept, the first dielectric layer 111 is formed of an inorganic dielectric material such as a silicon nitride, a silicon oxide, or the like. In an embodiment of the present inventive concept, the first dielectric layer 111 may be formed by a CVD, ALD, or PECVD process.

After forming the first dielectric layer 111, via holes are formed by selectively etching the first dielectric layer 111, and the first redistribution layer vias 112 are formed by filling the via holes with a conductive material.

Then, the first dielectric layer 111 is additionally deposited on the first redistribution layer vias 112 and the first dielectric layer 111, the additionally deposited first dielectric layer 111 is selectively etched to form openings (e.g., via holes), and the first redistribution layer lines 113 are formed by filling the openings with a conductive material.

Then, the first dielectric layer 111 is additionally deposited on the first redistribution layer lines 113 and the first dielectric layer 111, the additionally deposited first dielectric layer 111 is selectively etched to form via holes, and the second redistribution layer vias 114 are formed by filling the via holes with a conductive material.

In an embodiment of the present inventive concept, the first redistribution layer vias 112, the first redistribution layer lines 113, and the second redistribution layer vias 114 may include at least one of copper, aluminum, tungsten, nickel, gold, tin, titanium, or an alloy thereof. In an embodiment of the present inventive concept, the first redistribution layer vias 112, the first redistribution layer lines 113, and the second redistribution layer vias 114 may be formed by performing a sputtering process. In an embodiment of the present inventive concept, the first redistribution layer vias 112, the first redistribution layer lines 113, and the second redistribution layer vias 114 may be formed by performing an electrolytic plating process after forming a seed metal layer.

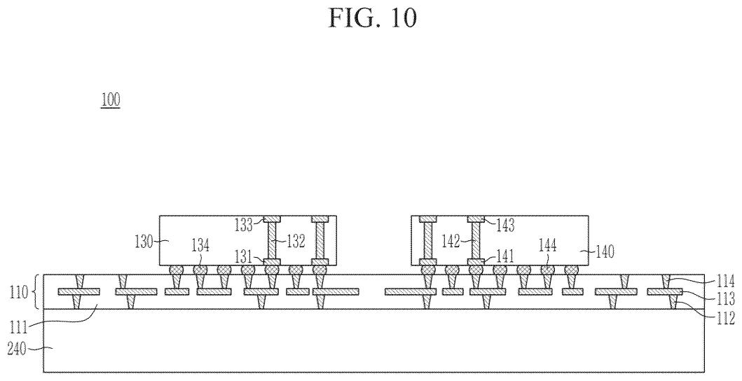

FIG. 10 illustrates a cross-sectional view showing a step of mounting the first semiconductor die 130 and the second semiconductor die 140 on the front side redistribution layer structure 110 as one of the steps of the method for manufacturing the semiconductor package 100 according to an embodiment of the present inventive concept.

Referring to FIG. 10, the first semiconductor die 130 and the second semiconductor die 140 are mounted on the front side redistribution layer structure 110 by flip chip bonding. The first semiconductor die 130 and the second semiconductor die 140 are positioned side by side and horizontally at a same level. The connection member 134 of the first semiconductor die 130 is bonded to the second redistribution layer via 114 of the front side redistribution layer structure 110, to electrically connect the first semiconductor die 130 and the front side redistribution layer structure 110 to each other. The connection member 144 of the second semiconductor die 140 is bonded to the second redistribution layer via 114 of the front side redistribution layer structure 110, to electrically connect the second semiconductor die 140 and the front side redistribution layer structure 110 to each other.

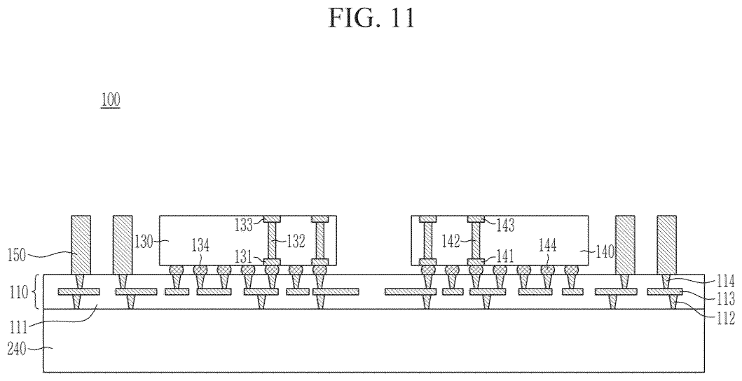

FIG. 11 illustrates a cross-sectional view showing a step of forming the conductive posts 150 on the front side redistribution layer structure 110 as one step of a method for manufacturing the semiconductor package 100 according to an embodiment of the present inventive concept.

Referring to FIG. 11, the conductive posts 150 are bonded to the second redistribution layer vias 114 of the front side redistribution layer structure 110 to be formed in the vertical direction. In an embodiment of the present inventive concept, the conductive posts 150 may be formed by performing a sputtering process. In an embodiment of the present inventive concept, the conductive posts 150 may be formed by performing an electrolytic plating process after forming a seed metal layer. In an embodiment of the present inventive concept, the conductive posts 150 may include at least one of copper, aluminum, tungsten, nickel, gold, silver, chromium, antimony, tin, titanium, or an alloy thereof.

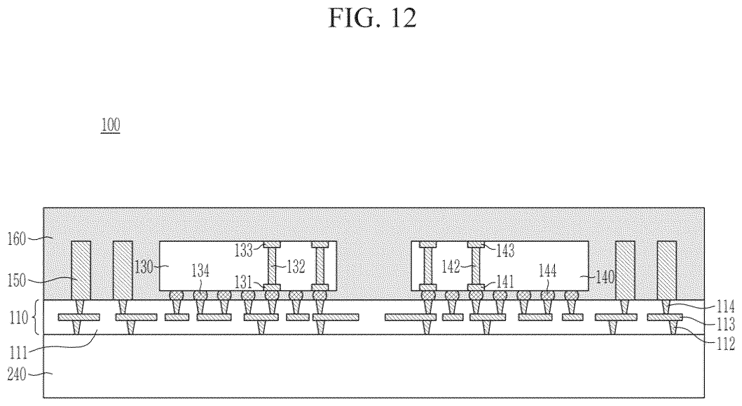

FIG. 12 illustrates a cross-sectional view showing a step of molding the conductive posts 150, the first semiconductor die 130 and the second semiconductor die 140 with the first molding material 160 on the front side redistribution layer structure 110 as one step of a method for manufacturing the semiconductor package 100 according to an embodiment of the present inventive concept.

Referring to FIG. 12, the conductive posts 150, the first semiconductor die 130, and the second semiconductor die 140 are molded with the first molding material 160 on the front side redistribution layer structure 110. For example, the first molding material 160 is formed on the conductive posts 150, the first semiconductor die 130, and the second semiconductor die 140. In an embodiment of the present inventive concept, the molding process with the first molding material 160 may include a compression molding or transfer molding process. In an embodiment of the present inventive concept, the first molding material 160 may include an epoxy molding compound (EMC).

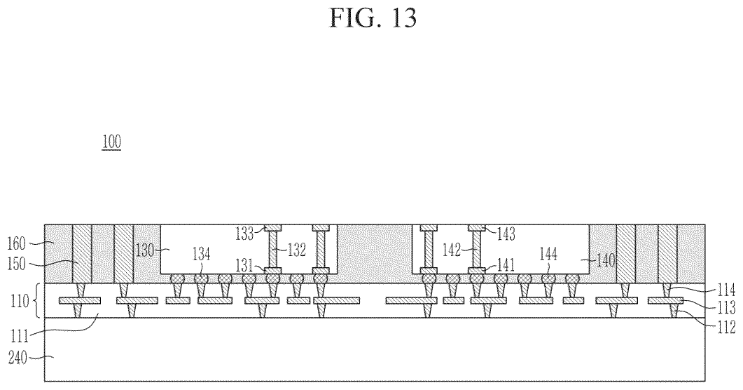

FIG. 13 illustrates a cross-sectional view showing a step of planarizing the first molding material 160 as one step of a method for manufacturing the semiconductor package according to an embodiment of the present inventive concept.

Referring to FIG. 13, chemical mechanical polishing (CMP) is performed to level an upper surface of the first molding material 160. The upper surface of the first molding material 160 is planarized by applying a CMP process. After performing the CMP process, upper surfaces of the conductive posts 150, upper surfaces of the second connection pads 133 of the first semiconductor die 130, and upper surfaces of the fourth connection pads 143 of the second semiconductor die 140 are exposed.

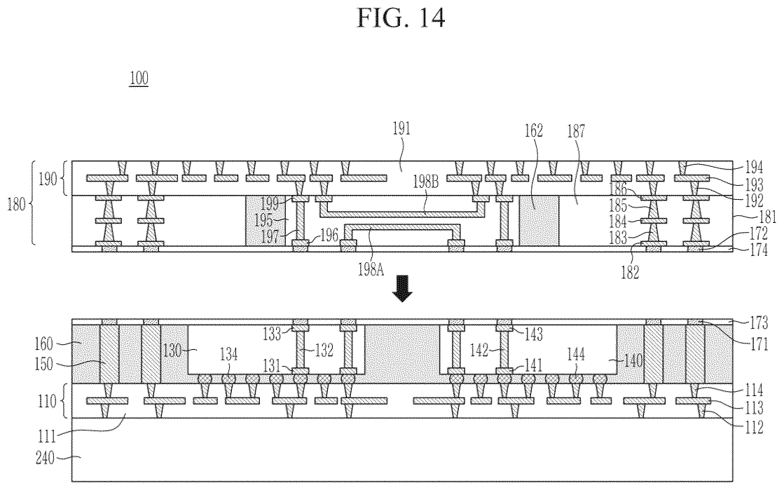

FIG. 14 illustrates a cross-sectional view showing a step of providing the interposer 180 for hybrid bonding as one step of a method for manufacturing the semiconductor package 100 according to an embodiment of the present inventive concept.

Referring to FIG. 14, the interposer 180 manufactured through the steps of FIG. 3 to FIG. 8 is provided. A first bonding pad 171 is positioned on the conductive posts 150, the second connection pads 133, and the fourth connection pads 143, and a first silicon insulating layer 173 is formed to at least partially surround side surfaces of the first bonding pads 171. A second bonding pad 172 is positioned on the lower surface of the first wiring layers 182 of the substrate 181 and the lower surface of the lower connection pad 196 of the bridge die 195, and a second silicon insulating layer 174 is formed to at least partially surround the second bonding pads 172.

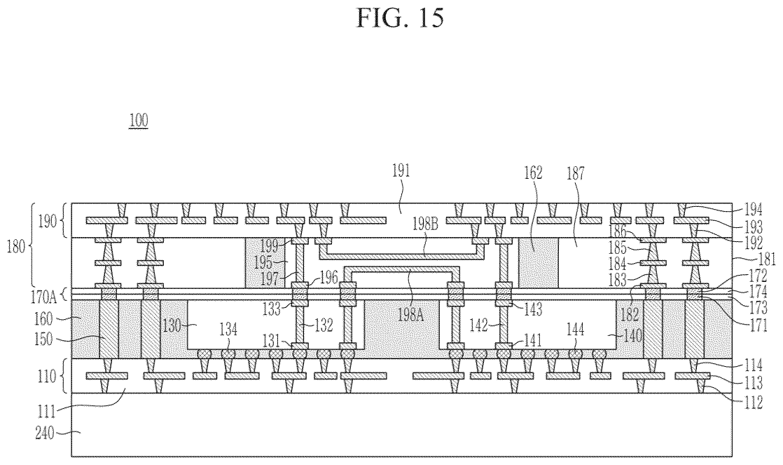

FIG. 15 illustrates a cross-sectional view showing a step of electrically connecting the interposer 180 to the conductive posts 150, the first semiconductor die 130 and the second semiconductor die 140 by hybrid bonding as one step of a method for manufacturing the semiconductor package 100 according to an embodiment of the present inventive concept.

Referring to FIG. 15, the first bonding pad 171, which is on the upper surfaces of the conductive posts 150, and a second bonding pad 172, which is on the lower surface of the substrate 181, may be bonded by metal-metal hybrid bonding. For example, the first bonding pad 171 may be directly bonded to the second bonding pad 172. In addition, the first bonding pad 171, which is on the upper surfaces of the first semiconductor die 130 and the second semiconductor die 140, and the second bonding pad 172, which is on the lower surface of the bridge die 195, may be bonded by metal-metal hybrid bonding. A metal bond is formed at an interface between the first bonding pad 171 and the second bonding pad 172 by metal-metal hybrid bonding. In an embodiment of the present inventive concept, the first bonding pad 171 and the second bonding pad 172 may each include copper. In an embodiment of the present inventive concept, the first bonding pad 171 and the second bonding pad 172 may be a metallic material to which hybrid bonding is applied.

Since the first bonding pad 171 and the second bonding pad 172 are made of a same material, an interface between the first bonding pad 171 and the second bonding pad 172 may disappear after hybrid bonding. Through the first bonding pad 171 and the second bonding pad 172, the substrate 181 may be electrically connected to the conductive posts 150, and the bridge die 195 may be electrically connected to the first semiconductor die 130 and the second semiconductor die 140.

The first silicon insulating layer 173 and the second silicon insulating layer 174 may be bonded by non-metal-non-metal hybrid bonding. For example, the first silicon insulating layer 173 and the second silicon insulating layer 174 may be directly bonded to each other. A covalent bond is formed at an interface between the first silicon insulating layer 173 and the second silicon insulating layer 174 by non-metal-non-metal hybrid bonding.

In an embodiment of the present inventive concept, the first silicon insulating layer 173 and the second silicon insulating layer 174 may include a silicon oxide or a TEOS forming oxide. In an embodiment of the present inventive concept, the first silicon insulating layer 173 and the second silicon insulating layer 174 may each include SiO₂. In an embodiment of the present inventive concept, the first silicon insulating layer 173 and the second silicon insulating layer 174 may each be a silicon nitride, a silicon oxynitride, or other suitable dielectric material. In an embodiment of the present inventive concept, the first silicon insulating layer 173 and the second silicon insulating layer 174 may each include SiN or SiCN.

The first silicon insulating layer 173 and the second silicon insulating layer 174 are made of a same material, and after hybrid bonding, an interface between the first silicon insulating layer 173 and the second silicon insulating layer 174 may disappear.

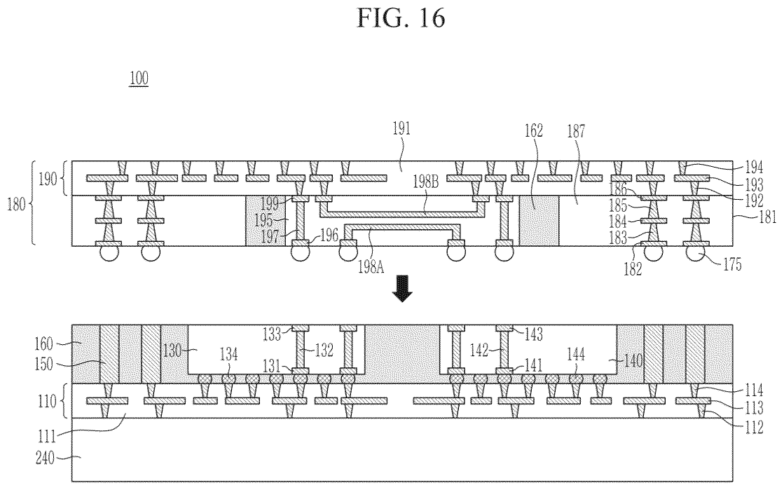

FIG. 16 illustrates a cross-sectional view showing a step of providing the interposer 180 for flip chip bonding, following FIG. 13, as one step of a method for manufacturing the semiconductor package 100 according to an embodiment of the present inventive concept.

Referring to FIG. 16, the interposer 180 manufactured through the steps of FIG. 3 to FIG. 8 is provided. The connection members 175 are positioned on the lower surface of the first wiring layers 182 of the substrate 181 and the lower surface of the lower connection pad 196 of the bridge die 195.

FIG. 17 illustrates a cross-sectional view showing a step of electrically connecting the interposer 180 to the conductive posts 150, the first semiconductor die 130, and the second semiconductor die 140 by flip chip bonding as one step of a method for manufacturing the semiconductor package 100 according to an embodiment of the present inventive concept.

Referring to FIG. 17, the interposer 180 is electrically connected to the conductive posts 150, the first semiconductor die 130, and the second semiconductor die 140 by the connection members 175.

The insulating member 176 is positioned between the interposer 180 and each of the conductive posts 150, the first semiconductor die 130, and the second semiconductor die 140 to at least partially surround the connection members 175. As such, by positioning the insulating member 176 in the above manner, stress between the interposer 180 in upper portion and the conductive posts 150, the first semiconductor die 130, and the second semiconductor die 140 in lower portion may be relieved or reduced.

In an embodiment of the present inventive concept, before mounting the interposer 180 on the conductive posts 150, the first semiconductor die 130, and the second semiconductor die 140, a non-conductive film (NCF) may be attached as an insulating member 176 on the conductive posts 150, the first semiconductor die 130, and the second semiconductor die 140. The non-conductive film (NCF) is adhered with adhesiveness. The non-conductive film (NCF) has an uncured state capable of being deformed by an external force. The non-conductive film (NCF) may be attached by heating at a temperature of about 170° C. to about 300° C. for about 1 s to about 20 s. Then, the interposer 180 is mounted on the non-conductive film (NCF). The connection members 175, which are provided in the interposer 180, may extend through the non-conductive film NCF to contact the conductive posts 150, the second connection pad 133 of the first semiconductor die 130, and the fourth connection pad 143 of the second semiconductor die 140.

In an embodiment of the present inventive concept, after bonding the interposer 180 on the conductive posts 150, the first semiconductor die 130, and the second semiconductor die 140 using the connection members 175, a molded under-fill (MUF) may be filled between the interposer 180 and each of the conductive posts 150, and the first semiconductor die 130, and the second semiconductor die 140.

FIG. 18 illustrates a cross-sectional view showing a step of mounting the third semiconductor die 210 and the fourth semiconductor die 220 on the back side redistribution layer structure 190 as one of the steps of the method for manufacturing the semiconductor package 100 according to an embodiment of the present inventive concept.

Referring to FIG. 18, the third semiconductor die 210 and the fourth semiconductor die 220 are mounted on the back side redistribution layer structure 190 by flip chip bonding. The third semiconductor die 210 and the fourth semiconductor die 220 are positioned side by side and horizontally at a same level. The connection member 211 of the third semiconductor die 210 may be bonded to the fourth redistribution layer via 194 of the back side redistribution layer structure 190, thereby electrically connecting the third semiconductor die 210 to the back side redistribution layer structure 190. The connection member 221 of the fourth semiconductor die 220 is bonded to the fourth redistribution layer via 194 of the back side redistribution layer structure 190, to electrically connect the fourth semiconductor die 220 and the back side redistribution layer structure 190 to each other.

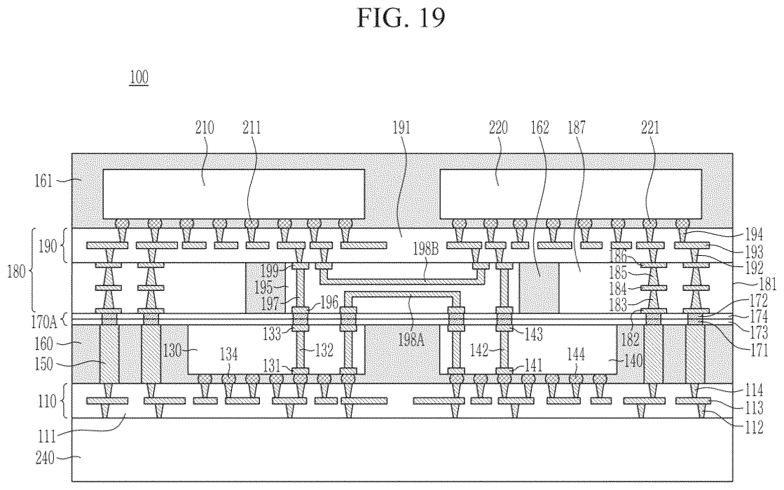

FIG. 19 illustrates a cross-sectional view showing a step of molding the third semiconductor die 210 and the fourth semiconductor die 220 with the second molding material 161 on the back side redistribution layer structure 190 as one step of a method for manufacturing the semiconductor package 100 according to an embodiment of the present inventive concept.

Referring to FIG. 19, the third semiconductor die 210 and the fourth semiconductor die 220 are molded with the second molding material 161 on the back side redistribution layer structure 190. For example, the second molding material 161 is formed on the third semiconductor die 210 and the fourth semiconductor die 220. In an embodiment of the present inventive concept, the molding process with the second molding material 161 may include a compression molding or transfer molding process. In an embodiment of the present inventive concept, the second molding material 161 may include an epoxy molding compound (EMC).

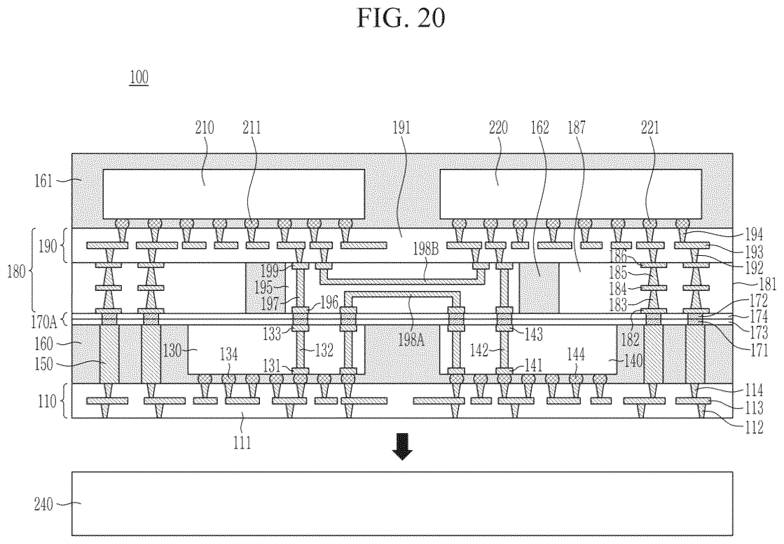

FIG. 20 illustrates a cross-sectional view showing a step of debonding the second carrier 240 from a lower surface of the front side redistribution layer structure 110 as one step of a method for manufacturing the semiconductor package 100 according to an embodiment of the present inventive concept.

Referring to FIG. 20, the first carrier 230 is de-bonded from the lower surface of the front side redistribution layer structure 110.

Thereafter, as illustrated in FIG. 1, the external connection structure 120 is positioned on the lower surface of the front side redistribution layer structure 110.

While the present inventive concept has been shown and described with reference to the embodiments thereof, it will be apparent to those of ordinary skill in the art that various changes in form and detail may be made thereto without departing from the spirit and scope of the present inventive concept.

What is claimed is:

1. A semiconductor package comprising:
a first redistribution layer structure;
a first semiconductor die disposed on the first redistribution layer structure;
a second semiconductor die disposed adjacent to the first semiconductor die on the first redistribution layer structure;
a molding material positioned on the first redistribution layer structure, and covering the first semiconductor die and the second semiconductor die;
a bridge die positioned on the molding material, the first semiconductor die, and the second semiconductor die, and electrically connecting the first semiconductor die and the second semiconductor die to each other;
a substrate positioned on the molding material, the first semiconductor die, and the second semiconductor die, and at least partially surrounding the bridge die; and
a second redistribution layer structure disposed on the bridge die and the substrate.

2. The semiconductor package of claim 1, wherein
the substrate includes an embedded trace substrate (ETS).

3. The semiconductor package of claim 1, wherein
the bridge die includes a silicon bridge.

4. The semiconductor package of claim 1, wherein
the first semiconductor die and the second semiconductor die exchange signals through the bridge die.

5. The semiconductor package of claim 1, wherein
the bridge die is positioned on a portion of an upper surface of the first semiconductor die and on a portion of an upper surface of the second semiconductor die.

6. The semiconductor package of claim 1, wherein
the first semiconductor die and the second semiconductor die each include a through silicon via (TSV).

7. The semiconductor package of claim 1, wherein
the first semiconductor die includes an application processor (AP).

8. The semiconductor package of claim 1, wherein
the second semiconductor die includes a memory semiconductor.

9. A semiconductor package comprising:
a first redistribution layer structure;
a first semiconductor die disposed on the first redistribution layer structure;
a second semiconductor die disposed adjacent to the first semiconductor die on the first redistribution layer structure;
a plurality of conductive posts disposed on the first redistribution layer structure;
a first molding material positioned on the first redistribution layer structure and covering the first semiconductor die, the second semiconductor die, and the plurality of conductive posts;
an interposer positioned on the first molding material, the plurality of conductive posts, the first semiconductor die, and the second semiconductor die;
a third semiconductor die disposed on the interposer;
a fourth semiconductor die disposed adjacent to the third semiconductor die on the interposer; and
a second molding material positioned on the interposer, and covering the third semiconductor die and the fourth semiconductor die,
wherein the interposer includes:
a bridge die configured to electrically connect the first semiconductor die and the second semiconductor die to each other;
a substrate positioned on the first molding material, the first semiconductor die, and the second semiconductor die, and at least partially surrounding the bridge die, wherein the substrate is electrically connected to the conductive posts; and
a second redistribution layer structure disposed on the bridge die and the substrate.

10. The semiconductor package of claim 9, wherein
upper surfaces of the plurality of conductive posts, an upper surface of the first semiconductor die, and an upper surface of the second semiconductor die are at a same level as each other.

11. The semiconductor package of claim 9, wherein
the substrate electrically connects the second redistribution layer structure to the first redistribution layer structure that is connected to the conductive posts.

12. The semiconductor package of claim 9, further comprising
an interconnection structure configured to electrically connect the interposer to the plurality of conductive posts, the first semiconductor die, and the second semiconductor die.

13. The semiconductor package of claim 12, wherein
the interconnection structure includes:
a plurality of first bonding pads disposed on upper surfaces of the plurality of conductive posts, the first semiconductor die, and the second semiconductor die;
a first silicon insulating layer at least partially surrounding the plurality of first bonding pads;
a plurality of second bonding pads disposed on a lower surface of the interposer; and
a second silicon insulating layer at least partially surrounding the plurality of second bonding pads.

14. The semiconductor package of claim 13, wherein
each first bonding pad of the first bonding pads is directly bonded to a corresponding second bonding pad of the second bonding pads.

15. The semiconductor package of claim 13, wherein
the first silicon insulating layer is directly bonded to the second silicon insulating layer.

16. The semiconductor package of claim 9, wherein
the first molding material and the second molding material each include an epoxy molding compound.

17. The semiconductor package of claim 9, wherein
the interposer further includes a third molding material covering the bridge die within the substrate, and
the third molding material includes an ajinomoto build-up film (ABF).

18. A manufacturing method for a semiconductor package, comprising:
mounting a first semiconductor die and a second semiconductor die on a first redistribution layer structure;
forming a plurality of conductive posts on the first redistribution layer structure;
molding the first semiconductor die, the second semiconductor die, and the conductive posts with a first molding material on the first redistribution layer structure;
providing an interposer, wherein the interposer includes:
a bridge die:
a substrate at least partially surrounding the bridge die; and
a second redistribution layer structure disposed on the substrate and the bridge die;
electrically connecting a lower surface of the substrate to the plurality of conductive posts, and electrically connecting a lower surface of the bridge die to the first semiconductor die and the second semiconductor die;
mounting a third semiconductor die and a fourth semiconductor die on the second redistribution layer structure; and
molding the third semiconductor die and the fourth semiconductor die with a second molding material on the second redistribution layer structure.

19. The manufacturing method of claim 18, wherein
the providing of the interposer includes:
attaching a bridge die and a substrate to at least partially surround the bridge die on a carrier;
molding the bridge die with a third molding material on the carrier; and
forming a redistribution layer structure on the substrate, the bridge die, and the third molding material.

20. The manufacturing method of claim 18, wherein
the electrically connecting of the lower surface of the substrate to the plurality of conductive posts and the electrically connecting of the lower surface of the bridge die to the first semiconductor die and the second semiconductor die are performed by hybrid bonding.
